(19) United States
(12) Patent Application Publication
(10) Pub. No.: US 2016/0211433 A1
(43) Pub. Date: Jul. 21, 2016

(54) THERMOELECTRIC CONVERSION MATERIAL AND THERMOELECTRIC CONVERSION ELEMENT

(71) Applicant: FUJIFILM Corporation, Tokyo (JP)

(72) Inventor: Takeyoshi KANO, Ashigarakami-gun (JP)

(73) Assignee: FUJIFILM Corporation, Tokyo (JP)

(21) Appl. No.: 15/086,510

(22) Filed: Mar. 31, 2016

Related U.S. Application Data
(63) Continuation of application No. PCT/JP2014/076056, filed on Sep. 30, 2014.

(30) Foreign Application Priority Data
Oct. 1, 2013 (JP) 2013-206361

(51) Int. Cl. H01L 35/24; C09D 5/24

(52) U.S. Cl. CPC H01L 35/24; C09D 5/24

(57) ABSTRACT

A thermoelectric conversion material containing (a) a carbon nanotube; and (b) a dispersing agent including a repeating unit represented by General Formula (1A) below and a repeating unit represented by General Formula (1B) below:

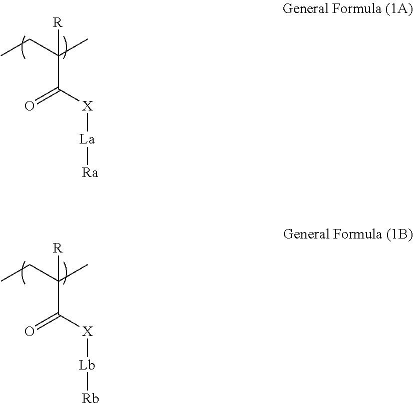

In General Formula (1A), Ra represents an electron-accepting group. La represents a single bond or a divalent linking group. R represents a hydrogen atom or an alkyl group having 1 to 4 carbon atoms. X represents an oxygen atom or —NH—.

In General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. Lb represents a single bond or a divalent linking group. R and X are identical to those in General Formula (1A).

### CROSS-REFERENCE TO RELATED APPLICATIONS

This application is a Continuation of PCT International Application No. PCT/JP2014/076056 filed on Sep. 30, 2014, which claims priority under 35 U.S.C. §119 (a) to Japanese Patent Application No. 2013-206361 filed on Oct. 1, 2013. Each of the above applications is hereby expressly incorporated by reference, in its entirety, into the present application.

### BACKGROUND OF THE INVENTION

1. Field of the Invention

The present invention relates to a thermoelectric conversion material and a thermoelectric conversion element manufactured using the same.

2. Description of the Related Art

Thermoelectric conversion materials that can mutually convert heat energy and electric energy are used in thermoelectric power generating elements and in thermoelectric conversion elements such as Peltier devices. Thermoelectric power generation achieved by applying a thermoelectric conversion material or a thermoelectric conversion element enables direct conversion from heat energy to electric power, does not require any moving parts, and is used in wrist watches that are operated by body temperature, as well as in power supplies for remote areas and power supplies used in space.

As one of indexes that evaluate the thermoelectric conversion performance of a thermoelectric conversion element, there is a dimensionless figure of merit ZT (hereinafter, in some cases, simply referred to as the figure of merit ZT). The figure of merit ZT is represented by Equation (A) below, and important factors for the enhancement of the thermoelectric conversion performance are the increase in the thermoelectromotive force S per absolute temperature (hereinafter, in some cases, referred to as the thermoelectromotive force) and electrical conductivity σ and the reduction of thermal conductivity κ.

Figure of merit ZT=S²·σ·T/κ (A)

In Equation (A), S (V/K): Thermoelectromotive force per absolute temperature (Seebeck coefficient)
σ (S/m): Electrical conductivity
κ (W/mK): Thermal conductivity
T (K): Absolute temperature

The thermoelectric conversion materials require favorable thermoelectric conversion performance, and thermoelectric conversion materials that have been mainly put into practical use at the moment are inorganic materials. However, inorganic materials need to undergo a complicated step to be processed into thermoelectric conversion elements, are expensive, and, in some cases, include harmful substances.

On the other hand, organic thermoelectric conversion elements can be manufactured at relatively low costs, and processes for forming films and the like are also easy, and thus, in recent years, active studies have been underway, and organic thermoelectric conversion materials and thermoelectric conversion elements manufactured using the organic thermoelectric conversion materials have been reported. In order to increase the figure of merit ZT of thermoelectric conversion, there is a demand for an organic material having a high Seebeck coefficient, high electric conductivity, and low thermal conductivity.

For example, JP2013-84947A proposes a thermoelectric conversion material having an excellent thermoelectromotive force for which an electroconductive polymer and a compound capable of improving the thermal excitation efficiency are used.

In addition, as organic materials having excellent electroconductive properties, carbon nanotubes are known. However, carbon nanotubes easily aggregate and have low dispersibility. Therefore, attempts are made to increase the dispersibility of carbon nanotubes. For example, JP2013-95821A proposes a composition containing an electroconductive polymer together with a carbon nanotube as a composition having excellent dispersibility of a carbon nanotube and proposes the use of the composition as a thermoelectric conversion material.

### SUMMARY OF THE INVENTION

An object of the present invention is to provide a thermoelectric conversion material which contains a carbon nanotube and a dispersing agent of the carbon nanotube, has favorable dispersibility of the carbon nanotube, and is excellent in terms of the thermoelectromotive force and a thermoelectric conversion element manufactured using the same.

The present inventors and the like carried out studies regarding compounds that improve the dispersibility of a carbon nanotube when being used together with the carbon nanotube. As a result, it was found that a particular polymer compound having an electron-accepting group and a steric repulsive group is capable of favorably dispersing a carbon nanotube in a solvent. Furthermore, it was found that a composition containing the compound and a carbon nanotube exhibits an excellent thermoelectromotive force and is useful as a thermoelectric conversion material. The invention has been completed on the basis of the above-described finding.

That is, according to the invention, the following means are provided:

<1> A thermoelectric conversion material containing (a) a carbon nanotube, and (b) a dispersing agent including a repeating unit represented by General Formula (1A) below and a repeating unit represented by General Formula (1B) below:

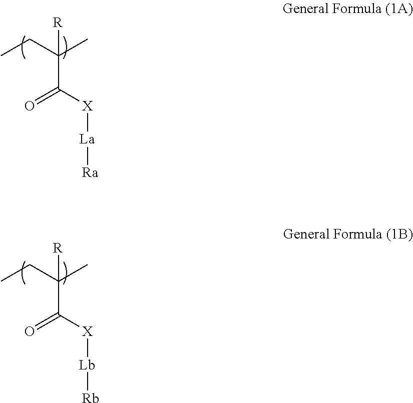

In General Formula (1A), Ra represents an electron-accepting group. La represents a single bond or a divalent linking group. R represents a hydrogen atom or an alkyl group having 1 to 4 carbon atoms. X represents an oxygen atom or —NH—.

In General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. Lb represents a single bond or a divalent linking group. R and X are identical to those in General Formula (1A).

<2> The thermoelectric conversion material according to <1>, in which (b) the dispersing agent satisfies Expression (I) below:

0.1 eV≦|HOMO of carbon nanotube|−|LUMO of dispersing agent|≦1.9 eV Expression (I)

In Expression (I), |HOMO of carbon nanotube| represents an absolute value of an energy level of a highest occupied molecular orbital (HOMO) of the carbon nanotube, and |LUMO of dispersing agent| represents an absolute value of an energy level of a lowest unoccupied molecular orbital (LUMO) of the dispersing agent, respectively.

<3> The thermoelectric conversion material according to <1> or <2>, in which, in General Formula (1A), Ra is a monovalent group derived from a perylene bisimide compound, a tetracyanoquinodimethane compound, a phthalocyanine compound, a C60 fullerene compound, or a C70 fullerene compound.

<4> The thermoelectric conversion material according to any one of <1> to <3>, in which, in General Formula (1B), Rb is a monovalent group derived from a poly(meth)acrylate compound.

<5> The thermoelectric conversion material according to any one of <1> to <4>, containing a solvent.

<6> A thermoelectric conversion element having, on a base material, a first electrode, a thermoelectric conversion layer, and a second electrode, in which the thermoelectric conversion layer is formed using the thermoelectric conversion material according to any one of <1> to <5>.

In the invention, a numerical value range described using “to” means a range including the values described before and after “to” as the lower limit value and the upper limit value.

In addition, in the invention, when an xxx group is mentioned as a substituent, the xxx group may have an arbitrary substituent. In addition, in case in which there are a plurality of groups indicated by the same reference signal, the groups may be identical to or different from each other.

Repeating structures illustrated by individual formulae do not have to be exactly the same repeating structures and may be different repeating structures as long as the repeating structures belong to the range represented by the formulae. For example, in case in which repeating structures have an alkyl group, repeating structures illustrated by individual formulae may be all repeating structures having a methyl group or may include repeating structures having a different alkyl group, for example, an ethyl group in addition to repeating structures having a methyl group.

The thermoelectric conversion material of the invention has favorable dispersibility of a carbon nanotube and is suitable for forming a thermoelectric conversion layer using a coating method. The thermoelectric conversion element of the invention comprising the thermoelectric conversion layer formed using the same material exhibits an excellent thermoelectromotive force.

The above-described and other characteristics and advantages of the invention will be more clarified by the following description with appropriate reference to the accompanying drawings.

### BRIEF DESCRIPTION OF THE DRAWINGS

FIG. 1 is a view schematically illustrating a section of an example of a thermoelectric conversion element of the present invention. The arrow in FIG. 1 indicates the direction of a temperature difference applied during the use of the element.

FIG. 2 is a view schematically illustrating a section of another example of the thermoelectric conversion element of the invention. The arrow in FIG. 2 indicates the direction of a temperature difference applied during the use of the element.

### DESCRIPTION OF THE PREFERRED EMBODIMENTS

A thermoelectric conversion material of the invention contains (a) a carbon nanotube and (b) a dispersing agent of the carbon nanotube as essential components and other components as necessary.

[(a) Carbon Nanotube]

As the carbon nanotube that is used in the invention (hereinafter, also referred to as CNT), there are a single-layer CNT that is a carbon film (graphene sheet) wound in a cylindrical shape, a bilayer CNT that is made of two graphene sheets wound in a concentric shape, and a multilayer CNT that is made of a plurality of graphene sheets wound in a concentric shape. In the invention, each of a single-layer CNT, a bilayer CNT, and a multilayer CNT may be used singly, or two or more kinds thereof may be used in combination. Particularly, a single-layer CNT and a bilayer CNT which have excellent properties in terms of electroconductive properties and semiconductor characteristics are preferably used, and a single-layer CNT is more preferably used.

In the case of a single-layer CNT, the symmetry of a spiral structure based on the orientation of hexagons of graphene in a graphene sheet is referred to as the axial chirality, and the two-dimensional lattice vector of a 6-membered ring from a standard point on graphene is referred to as the chiral vector. (n, m) obtained by indexing the chiral vector is referred to as the chiral index, and graphene is classified into metallic graphene and semiconductor graphene using this chiral index. Specifically, graphene having (n-m) that is a multiple of 3 exhibits metallic properties, and graphene having (n-m) that is not a multiple of 3 exhibits semiconductor properties.

A single-layer CNT that is used in the invention may be a semiconductor CNT or a metallic CNT, and both a semiconductor CNT and a metallic CNT may be jointly used. In addition, CNT may include a metal, and CNT including a molecule of a fullerene or the like (particularly, CNT including fullerene is referred to as a peapod) may also be used.

CNT can be manufactured using an arc discharge method, a chemical vapor deposition method (hereinafter, referred to as a CVD method), a laser application method, or the like. CNT that is used in the invention may be obtained using any method, but CNT obtained using an arc discharge method or a CVD method is preferred.

During the manufacturing of CNT, there are cases in which a fullerene or graphite and amorphous carbon are generated at the same time as byproducts. CNT may be purified in order to remove these byproducts. A method for purifying CNT is not particularly limited, and examples thereof include methods such as washing, centrifugal separation, filtration, oxidation, and chromatography. Additionally, an acid treatment using nitric acid, sulfuric acid, or the like and an ultrasonic treatment are also effective for removing impurities. It is more preferable to separate and remove impurities using a filter together with the above-described purification method from the viewpoint of improving the purity.

After purification, the obtained CNT may be used as it is. In addition, since CNT is generally generated in a string shape, CNT may be used after being cut into a desired length depending on the applications. CNT can be cut into a short fiber shape by means of an acid treatment using nitric acid, sulfuric acid, or the like, an ultrasonic treatment, or a frost shattering method. In addition, it is also preferable to separate impurities using a filter together with the above-described cutting method from the viewpoint of improving the purity.

In the invention, not only cut CNT but also CNT produced in a short fiber shape in advance can be used in the same manner. The above-described short fiber-shaped CNT is obtained in a shape in which CNT is aligned in a direction vertical to the substrate surface by, for example, forming a catalyst metal such as iron or cobalt on a substrate and growing CNT in a vapor phase on the surface by thermally decomposing a carbon compound at 700° C. to 900° C. using a CVD method. The short fiber-shaped CNT produced in the above-described manner can be pulled out from the substrate using a method such as peeling. In addition, the short fiber-shaped CNT can be obtained by supporting a catalyst metal on a porous support such as porous silicon or an anodized film of alumina and growing CNT on the surface thereof using a CVD method. It is also possible to produce an aligned short fiber-shaped CNT using a method in which a molecule such as iron phthalocyanine including a catalyst metal in the molecule is used as a raw material and CVD is performed in an argon/hydrogen gas flow, thereby producing CNT on the substrate. Furthermore, it is also possible to obtain a short fiber-shaped CNT aligned on a SiC crystal surface using an epitaxial growth method.

The average length of CNT is not particularly limited; however, from the viewpoint of easy manufacturing, film-forming properties, electroconductive properties, and the like, the average length thereof is preferably 0.01 μm to 1,000 μm and more preferably 0.1 μm to 100 μm. In addition, the average diameter of CNT is not particularly limited; however, from the viewpoint of durability, transparency, film-forming properties, electroconductive properties, and the like, the average diameter thereof is preferably 0.4 nm to 100 nm (more preferably 50 nm or smaller and still more preferably 15 nm or smaller).

The content of the carbon nanotube in the thermoelectric conversion material is preferably 5% by mass to 80% by mass, more preferably 5% by mass to 70% by mass, and particularly preferably 5% by mass to 50% by mass of the total solid content of the thermoelectric conversion material, that is, in a thermoelectric conversion layer from the viewpoint of the thermoelectric conversion performance.

Only one carbon nanotube may be used singly, or two or more kinds thereof may be used in combination.

[(b) Dispersing Agent of Carbon Nanotube]

The dispersing agent that is used in the invention is a polymer compound including a repeating unit represented by General Formula (1A) below and a repeating unit represented by General Formula (1B) below. The dispersing agent has an electron-accepting group and a steric repulsive group. The electron-accepting group also functions as an anchoring group to the carbon nanotube. Due to the above-described structure, the dispersing agent increases the dispersibility of a carbon nanotube in the thermoelectric conversion material and, furthermore, makes a thermoelectric conversion element comprising a thermoelectric conversion layer formed of the above-described material exhibit an excellent thermoelectromotive force. The mechanism thereof is not yet clear but is assumed as described below.

That is, when the carbon nanotube and the dispersing agent of the invention are blended with a solvent or a resin, the dispersing agent is anchored to the carbon nanotube due to the action of the anchoring group. The carbon nanotube particles to which the dispersing agent is anchored are repulsed from each other due to the action of the steric repulsive group in the dispersing agent and thus become incapable of easily aggregating. As a result, the dispersibility of the carbon nanotube becomes favorable. When the dispersing agent is used together with the carbon nanotube in the thermoelectric conversion material, it is possible to obtain a thermoelectric conversion material having excellent dispersibility of the carbon nanotube. The above-described thermoelectric conversion material is extremely suitable for forming a thermoelectric conversion layer using a coating method.

Furthermore, when the dispersing agent has the electron-accepting group (anchoring group), the thermal excitation efficiency from the carbon nanotube improves, and the number of thermally-excited carriers increases, and thus the thermoelectromotive force of the thermoelectric conversion material improves. As a result, the thermoelectric conversion performance improves.

The dispersing agent is preferably a compound satisfying Expression (I) below:

0.1 eV≦|HOMO of carbon nanotube|−|LUMO of dispersing agent|≦1.9 eV Expression (I)

In Expression (I), |HOMO of carbon nanotube| represents an absolute value of an energy level of a highest occupied molecular orbital (HOMO) of the carbon nanotube, and |LUMO of dispersing agent| represents an absolute value of an energy level of a lowest unoccupied molecular orbital (LUMO) of the dispersing agent, respectively.

The lowest unoccupied molecular orbital (LUMO) of the dispersing agent has a lower energy level than the LUMO of the carbon nanotube and functions as the acceptor level of a thermally-excited electron generated from the highest occupied molecular orbital (HOMO) of the carbon nanotube.

When the absolute value of the energy level of the HOMO of the carbon nanotube and the absolute value of the energy level of the LUMO of the dispersing agent has a relationship that satisfies Expression (I), the thermal excitation efficiency improves, and the number of thermally-excited carriers increases, and thus the thermoelectromotive force of the thermoelectric conversion material become excellent, which is preferable.

Meanwhile, regarding the HOMO energy levels and the LUMO energy levels of the carbon nanotube and the dispersing agent, the HOMO energy level can be measured by means of photoelectron spectroscopy after a single coated film (glass substrate) of each component is produced. The LUMO energy level can be calculated by measuring the band gap using an ultraviolet and visible spectrophotometer and then adding the band gap to the previously-measured HOMO energy level. In the invention, as the energy levels of the HOMO and the LUMO of the carbon nanotube and the dispersing agent, values measured and calculated using the above-described methods will be used.

The dispersing agent of the invention is a copolymer including a repeating unit represented by General Formula (1A) below and a repeating unit represented by General Formula (1B) below:

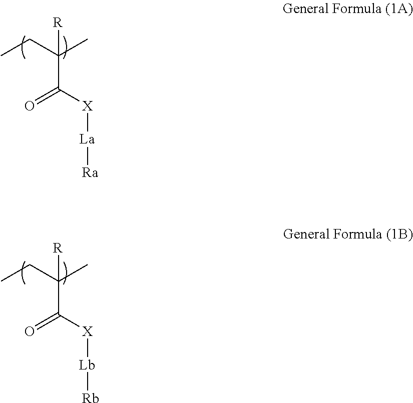

In General Formula (1A), Ra represents an electron-accepting group. La represents a single bond or a divalent linking group. R represents a hydrogen atom or an alkyl group having 1 to 4 carbon atoms. X represents an oxygen atom or —NH—.

In General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms. Lb represents a single bond or a divalent linking group. R and X are identical to those in General Formula (1A).

As Ra in General Formula (1A), the electron-accepting group is a monovalent group derived from an electron acceptor compound and functions as an electron acceptor so as to increase the thermal excitation efficiency and also functions as an anchoring group to the carbon nanotube.

Ra is preferably a monovalent group derived from a perylene bisimide compound, a tetracyanoquinodimethane compound, a phthalocyanine compound, a C60 fullerene compound, or a C70 fullerene compound.

As the perylene bisimide compound, any compounds may be used as long as the compounds have a perylene bisimide skeleton, and specific examples thereof include the following compounds 1 to 15.

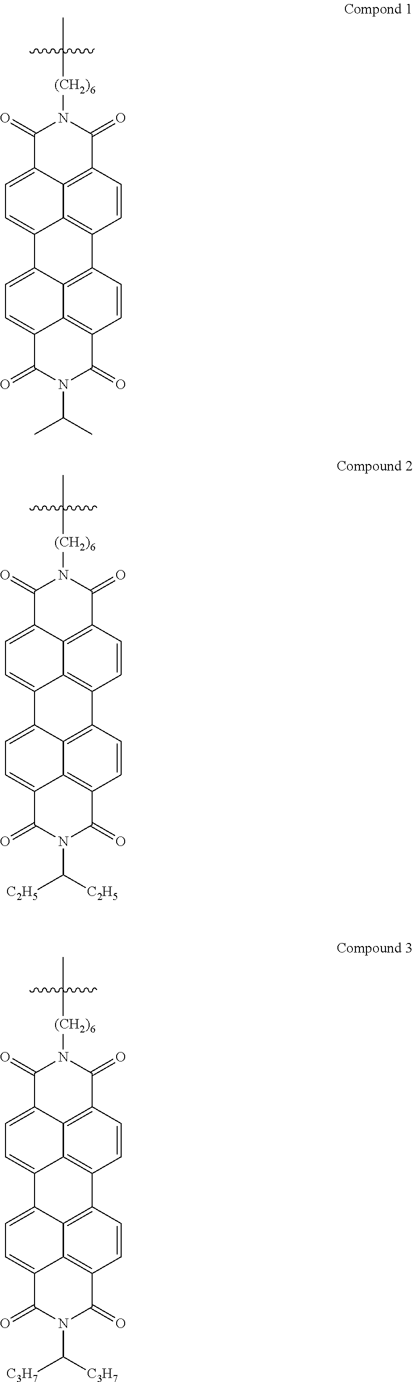

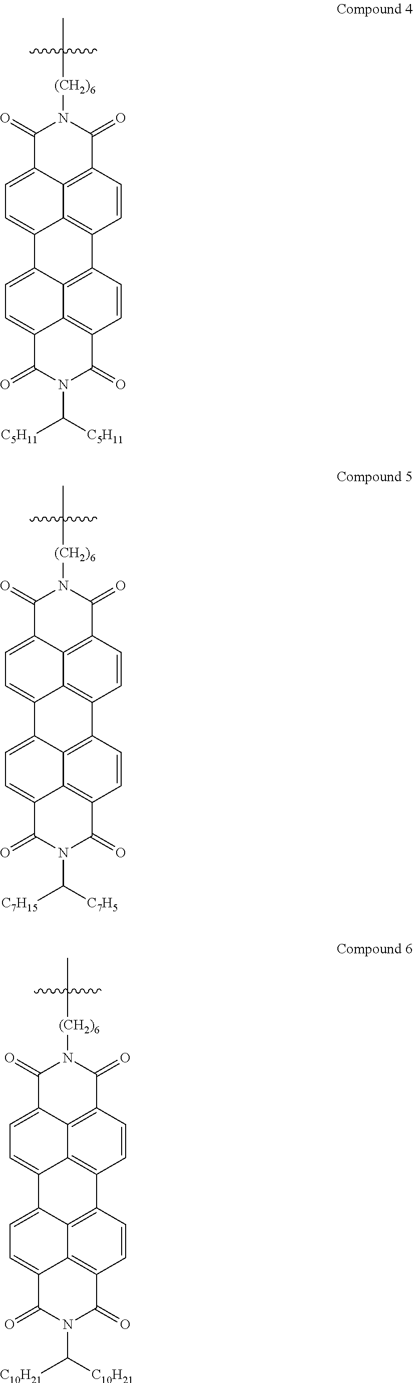

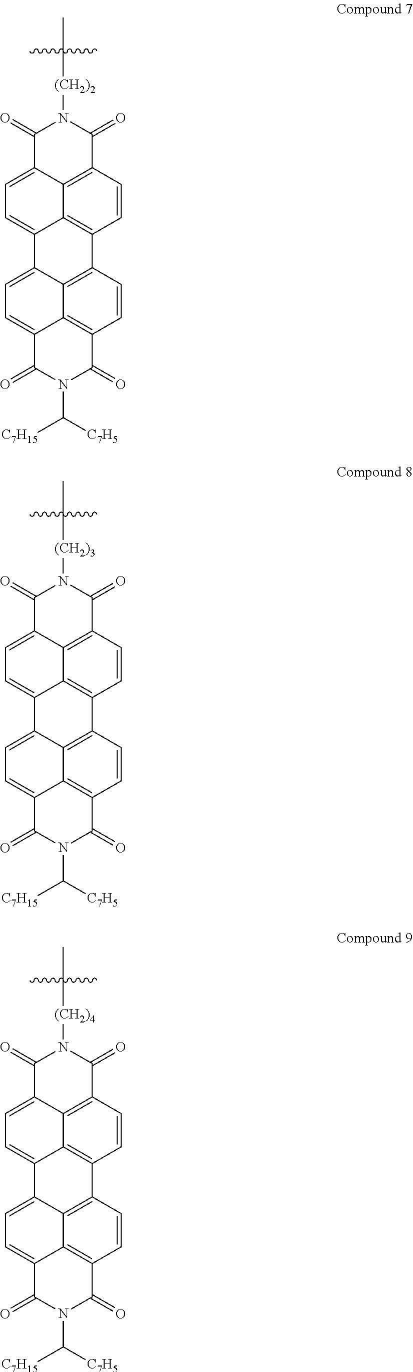

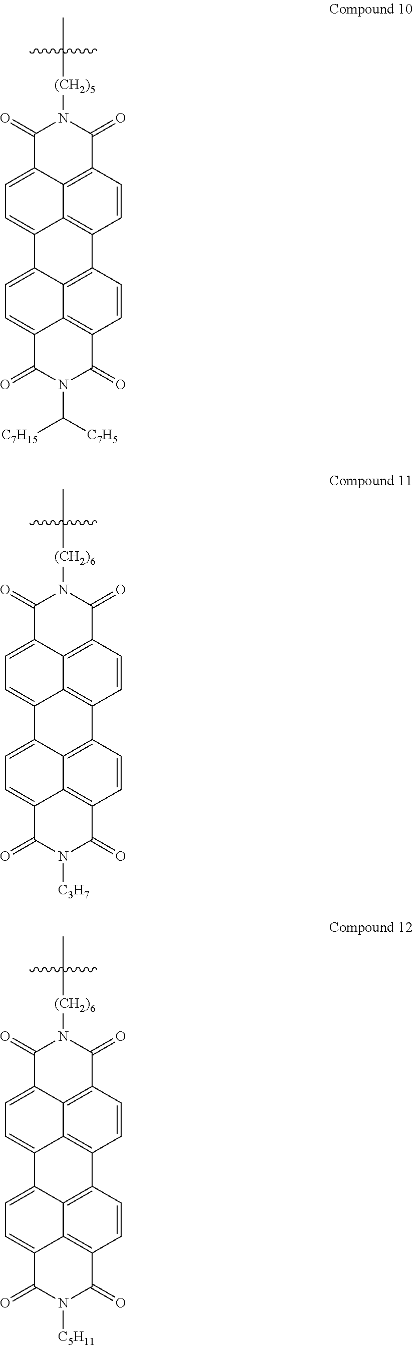

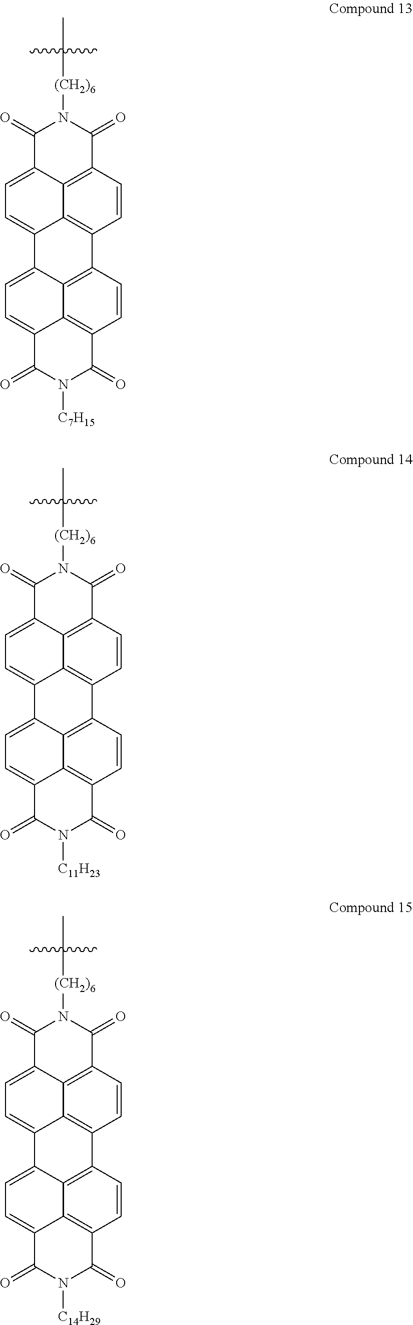

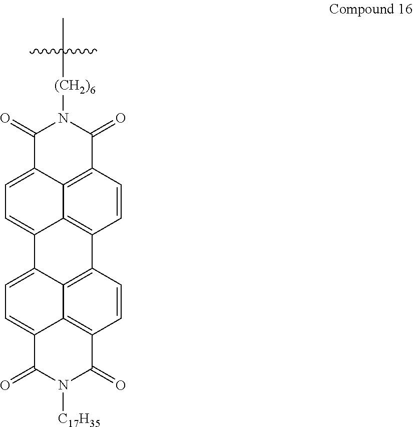

From the viewpoint of the solubility, the perylene bisimide compound is preferably the compounds 4 to 6, 9, 10, 14, and 15.

As the tetracyanoquinodimethane compound, any compounds may be used as long as the compounds have a tetracyanoquinodimethane skeleton, and specific examples thereof include the following compounds 1 to 6.

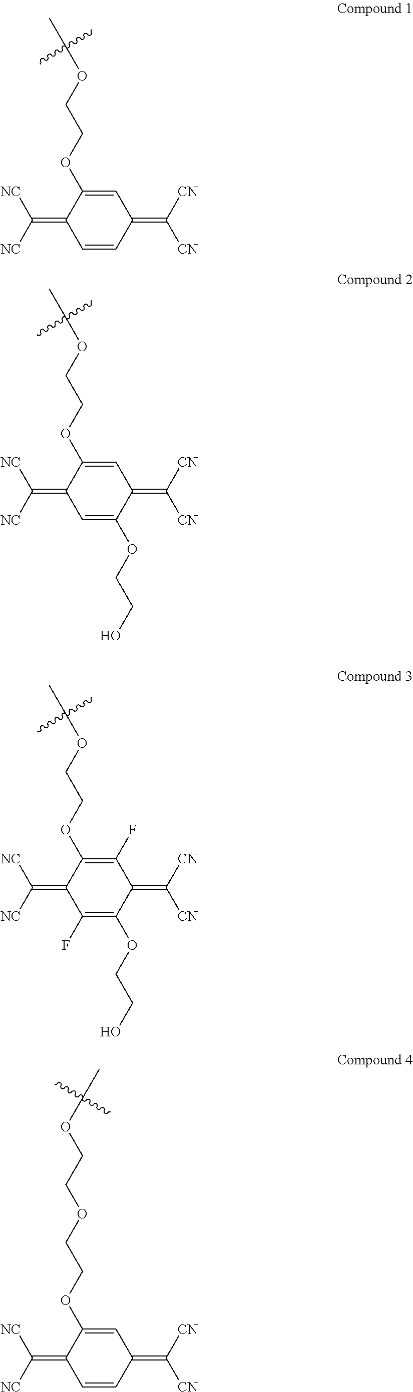 [SMILES: *OCCOc1cc(=C(C#N)C#N)ccc1=C(C#N)C#N ; *OCCOc1cc(=C(C#N)C#N)c(OCCO)cc1=C(C#N)C#N ; *OCCOc1c(F)c(=C(C#N)C#N)c(OCCO)c(F)c1=C(C#N)C#N ; *OCCOCCOc1cc(=C(C#N)C#N)ccc1=C(C#N)C#N]

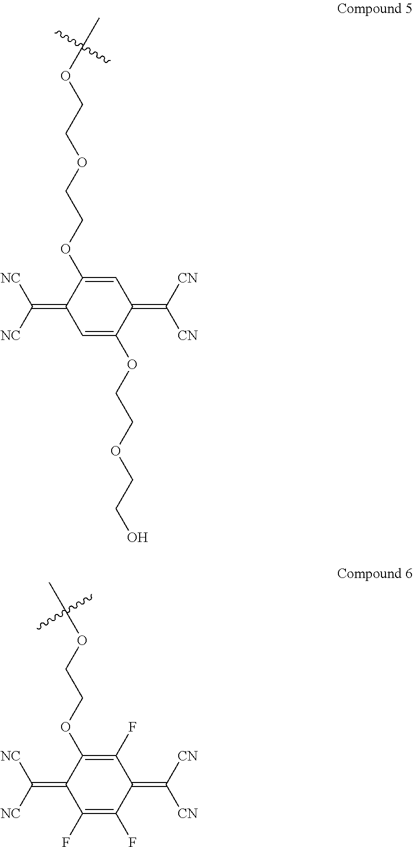 [SMILES: *OCCOCCOc1cc(=C(C#N)C#N)c(OCCOCCO)cc1=C(C#N)C#N ; *OCCOc1c(F)c(=C(C#N)C#N)c(F)c(F)c1=C(C#N)C#N]

From the viewpoint of the depth of the LUMO level and easy synthesis, the tetracyanoquinodimethane compound is preferably the compounds 1, 2, 3, and 6.

As the phthalocyanine compound, any compounds may be used as long as the compounds have a phthalocyanine skeleton, and specific examples thereof include copper phthalocyanine, bismuth phthalocyanine, antimony phthalocyanine, cobalt phthalocyanine, zinc phthalocyanine, lead phthalocyanine, tin phthalocyanine, vanadium phthalocyanine, titanium phthalocyanine, uranium phthalocyanine, magnesium phthalocyanine, fluorinated copper phthalocyanine, fluorinated bismuth phthalocyanine, fluorinated antimony phthalocyanine, fluorinated cobalt phthalocyanine, fluorinated zinc phthalocyanine, fluorinated lead phthalocyanine, fluorinated tin phthalocyanine, fluorinated vanadium phthalocyanine, fluorinated titanium phthalocyanine, and fluorinated uranium phthalocyanine. Among these, copper phthalocyanine, zinc phthalocyanine, fluorinated copper phthalocyanine, and fluorinated zinc phthalocyanine are preferred.

As the C60 fullerene compound, any compounds may be used as long as the compounds have a C60 fullerene skeleton, and specific examples thereof include C60 pyrrolidine tris-acid, C60 pyrrolidine tris-acid ethyl ester, Bis [60] Phenyl-C61-Butyricacid-Methyl ester (PCBM), [60] Phenyl-C61-Butyricacid-Methyl ester (PCBM), [60] Phenyl-C61-Butyricacid-butyl ester (PCBB), [60] Phenyl-C61-Butyricacid-Octyl ester (PCBO), and [60] Thienyl-C61-Butyricacid-methyl ester (ThCBM). Among these, [60] Phenyl-C61-Butyricacid-Methyl ester (PCBM), [60] Phenyl-C61-Butyricacid-butyl ester (PCBB), and [60] Phenyl-C61-Butyricacid-Octyl ester (PCBO) are preferred.

As the C70 fullerene compound, any compounds may be used as long as the compounds have a C70 fullerene skeleton, and specific examples thereof include [70] PCBM, [70] PCBB, [70] PCBO, and [70] PCBM. Among these, [70] PCBM is preferred.

In General Formula (1A), examples of the divalent linking group as La include an alkylene group, —O—, —CO—, —COO—, —CONH—, —NR¹¹—, —N⁺R¹¹R¹²—, —S—, —S(═O)—, and divalent groups obtained by combining the above-described divalent linking groups. Here, each of R¹¹ and R¹² independently represents a hydrogen atom or an alkyl group, and the number of carbon atoms in the alkyl group is preferably 1 or 2. The alkylene group may have a substituent, and examples of the substituent include a hydroxyl group, a halogen atom, an alkyl group, an alkoxy group, an amino group, and an ammonium group.

The number of carbon atoms in the alkylene group is preferably 1 to 7.

La is preferably an alkylene group, a divalent group obtained by combining an alkylene group and —O—, or a divalent group obtained by combining an alkylene group, —O—, and —CO—. In a case in which a plurality of groups are combined together, La more preferably bonds with X through the alkylene group.

The alkyl group as R may have any of a straight shape, a branched shape, and a cyclic shape and is preferably a straight alkyl group. The alkyl group may be substituted, and a substituent is preferably a halogen atom, an oxygen atom, or a sulfur atom. The number of carbon atoms in the alkyl group is preferably 1 to 3 and more preferably 1 or 2.

R is preferably an alkyl group having 1 or 2 carbon atoms and more preferably a methyl group.

X is preferably an oxygen atom.

Specific examples of the repeating unit represented by General Formula (1A) (hereinafter, also referred to as repeating unit (1A)) will be illustrated below, but the invention is not limited thereto.

Hereinafter, C70 in the examples of the repeating unit (1A) represents a C70 fullerene compound.

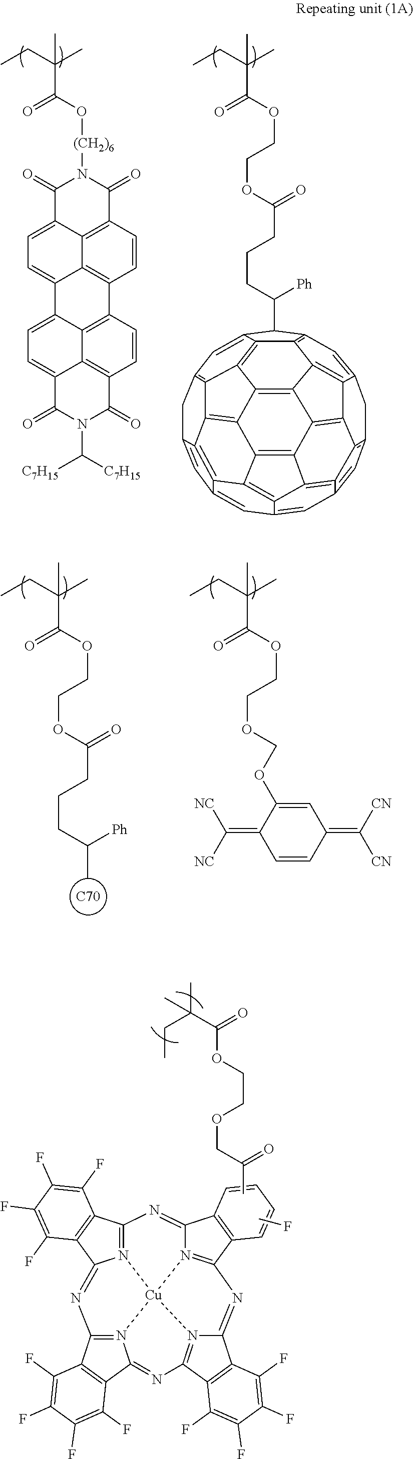

Rb in General Formula (1B) functions as the steric repulsive group.

The alkyl group as Rb may have any of a straight shape, a branched shape, and a cyclic shape and is preferably a straight alkyl group. The number of carbon atoms in the alkyl group is 5 or more, preferably 5 to 20, and more preferably 6 to 20. The alkyl group may have a substituent.

In case in which Rb is a monovalent group derived from a polyalkylene oxide compound, a poly(meth)acrylate compound, a polysiloxane compound, a polyacrylonitrile compound, or a polystyrene compound, Rb is preferably bonded with Lb at the terminal group of a polymer main chain thereof.

The repeating number of individual monomers constituting the polyalkylene oxide compound, the poly(meth)acrylate compound, the polysiloxane compound, the polyacrylonitrile compound, and the polystyrene compound is preferably 30 to 5,000 and more preferably 30 to 1,000.

The polyalkylene oxide compound, the poly(meth)acrylate compound, the polysiloxane compound, the polyacrylonitrile compound, or the polystyrene compound may have a substituent.

Specific examples of the polyalkylene oxide compound include polyethylene oxide, polypropylene oxide, and polybutylene oxide, and polyethylene oxide is preferred.

Specific examples of the poly(meth)acrylate compound include poly(methyl methacrylate), poly(isobutyl methacrylate), poly(ethyl methacrylate), poly(propyl methacrylate), poly(isopropyl methacrylate), poly(isobornyl methacrylate), poly(2-ethylhexyl methacrylate), poly(cyclohexyl methacrylate), poly(stearyl methacrylate), poly(tetrahydrofurfuryl methacrylate), poly(tridecyl methacrylate), poly(benzyl methacrylate), and poly(lauryl methacrylate), and poly(methyl methacrylate) and poly(isobutyl methacrylate) are preferred.

Specific examples of the polysiloxane compound include dimethylpolysiloxane and diethylpolysiloxane, and dimethylpolysiloxane is preferred.

Specific examples of the polyacrylonitrile compound include polyacrylonitrile.

Specific examples of the polystyrene compound include polystyrene and poly(4-methoxystyrene), and polystyrene is preferred.

Rb is preferably a monovalent group derived from the poly(meth)acrylate compound or the polystyrene compound and more preferably a monovalent group derived from the poly(meth)acrylate compound.

Examples of the divalent linking group as Lb include an alkylene group, —O—, —CO—, —COO—, —CONH—, —NR¹¹—, —N⁺R¹¹R¹²—, —S—, —S(═O)—, and divalent groups obtained by combining the above-described divalent linking groups. Here, each of R¹¹ and R¹² independently represents a hydrogen atom or an alkyl group, and the number of carbon atoms in the alkyl group is preferably 1 or 2. The alkylene group may have a substituent, and examples of the substituent include a hydroxyl group, a halogen atom, an alkyl group, an alkoxy group, an amino group, an ammonium group, and an ester group. The number of carbon atoms in the alkylene group is preferably 1 to 7. In addition, the number of carbon atoms in Lb is preferably 1 to 20 and more preferably 1 to 10.

Lb is preferably a divalent group obtained by combining an alkylene group, —O—, —CO—, and —S—. In this case, Lb is more preferably bonded with X through the alkylene group and bonded with Rb through —S—.

R and X in General Formula (1B) are identical to those in General Formula (1A), and preferred ranges thereof are also the same.

Specific examples of the repeating unit represented by General Formula (1B) (hereinafter, also referred to as repeating unit (1B)) will be illustrated below, but the invention is not limited thereto. Meanwhile, in the following specific examples, each of n and m represents an integer of 1 or greater:

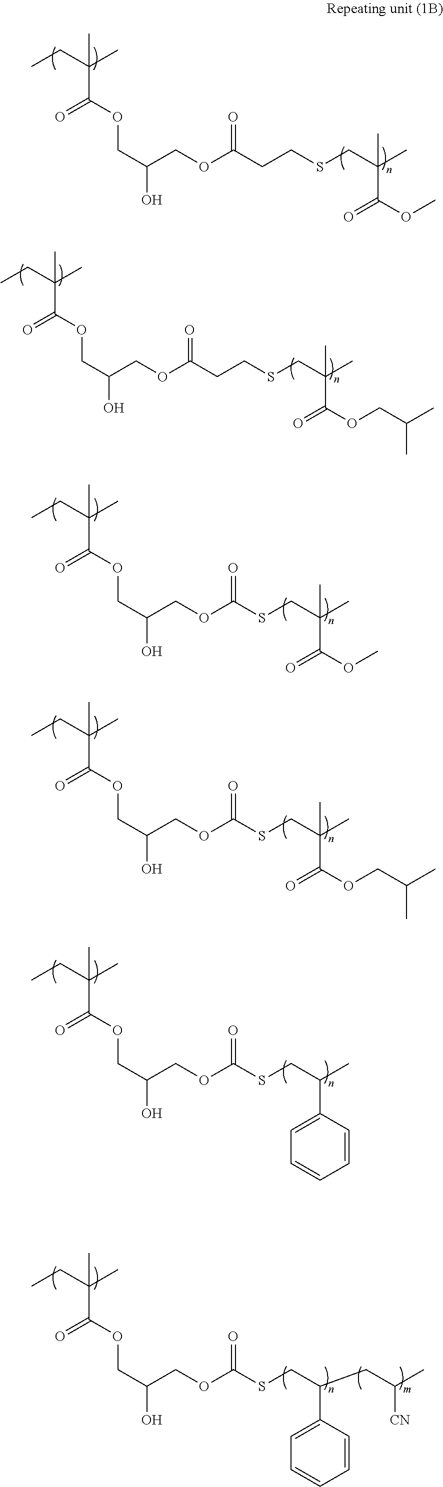

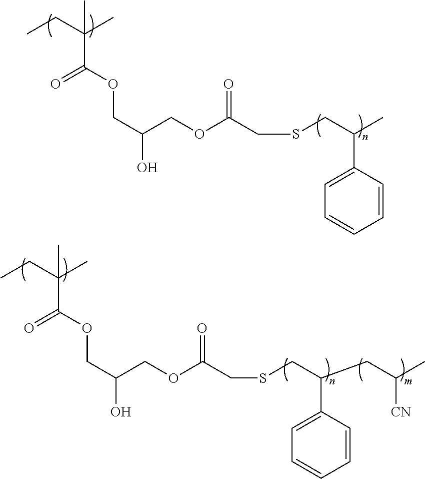

Specific examples of a combination of the repeating unit represented by General Formula (1A) and the repeating unit represented by General Formula (1B) will be illustrated below, but the invention is not limited thereto. Meanwhile, in the following specific examples, each of n and m represents an integer of 1 or greater:

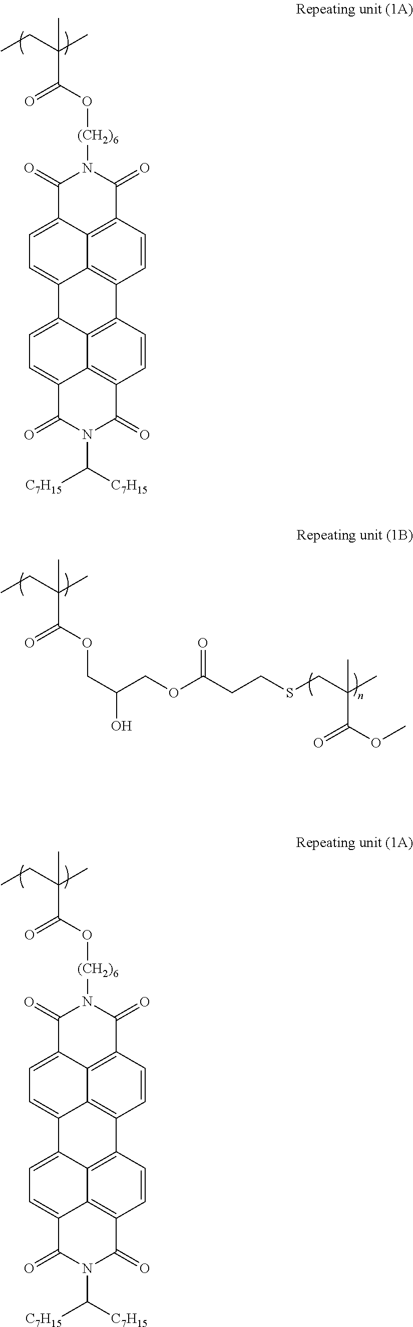

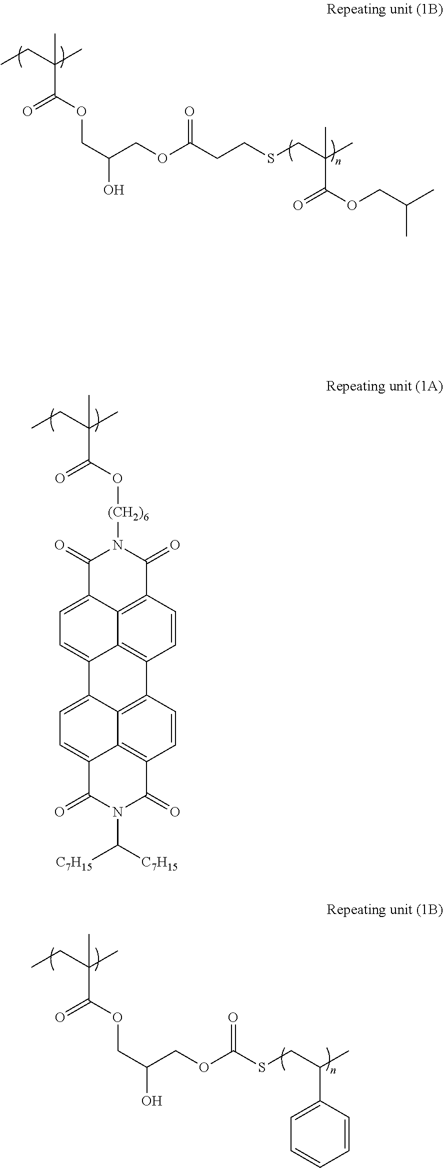

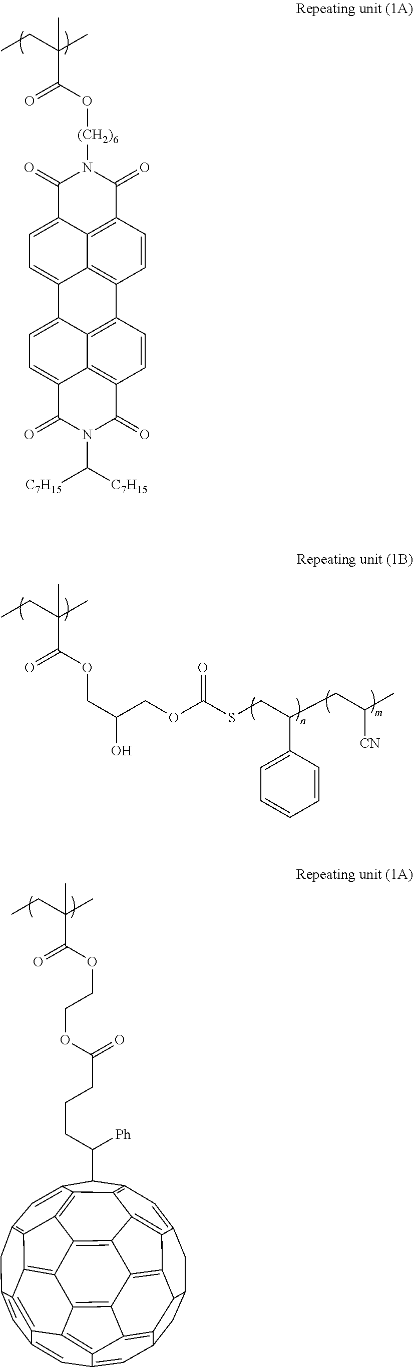

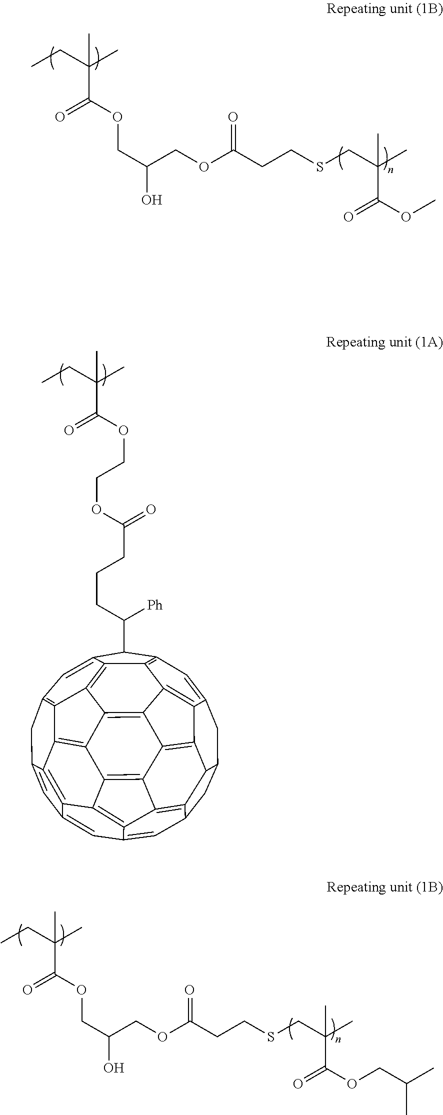

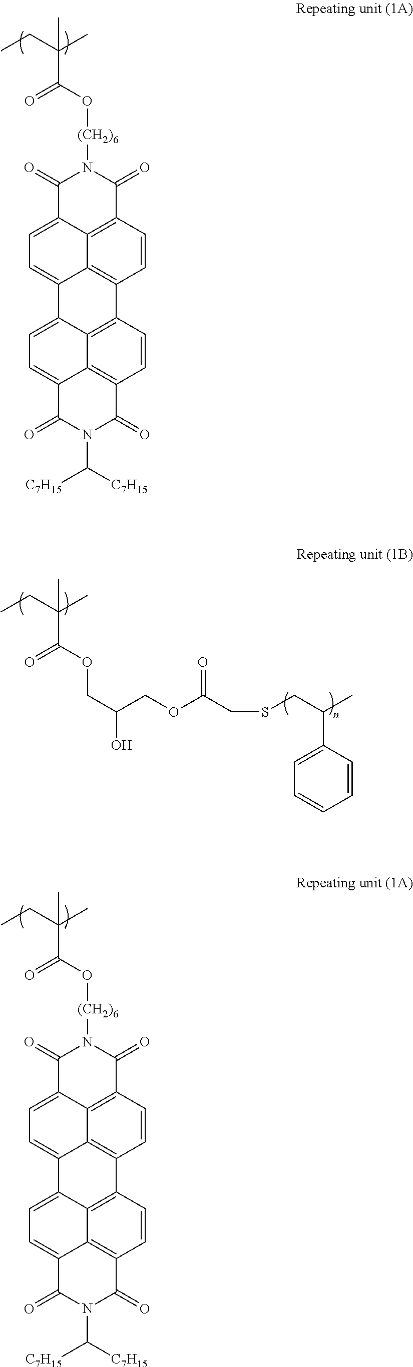

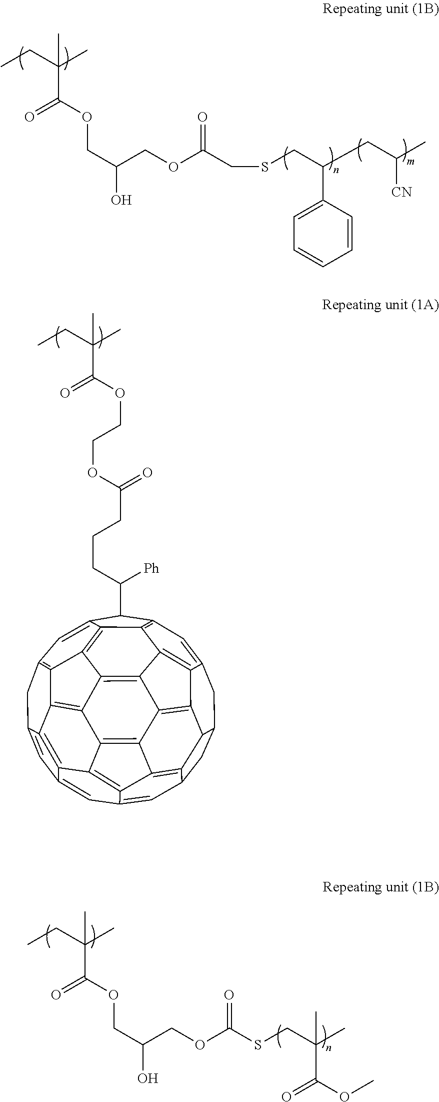

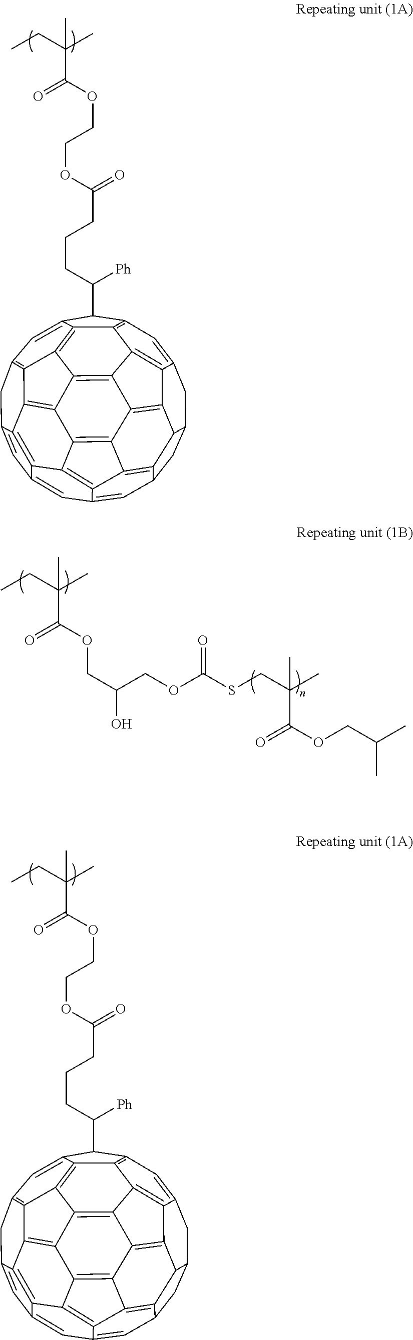

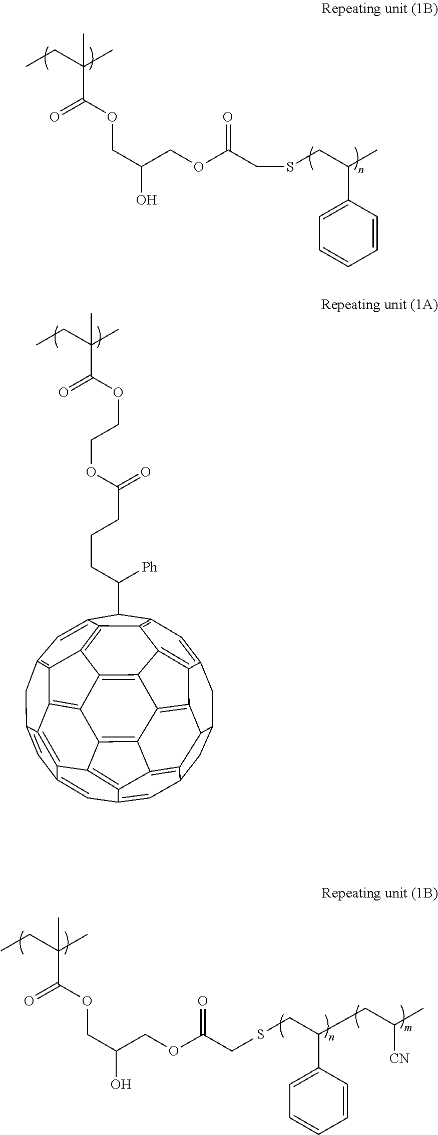

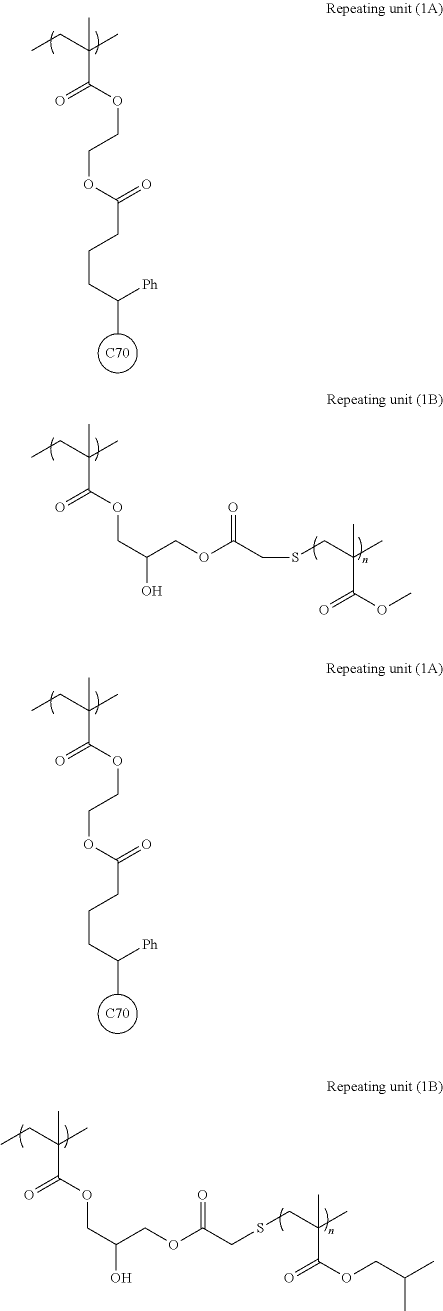

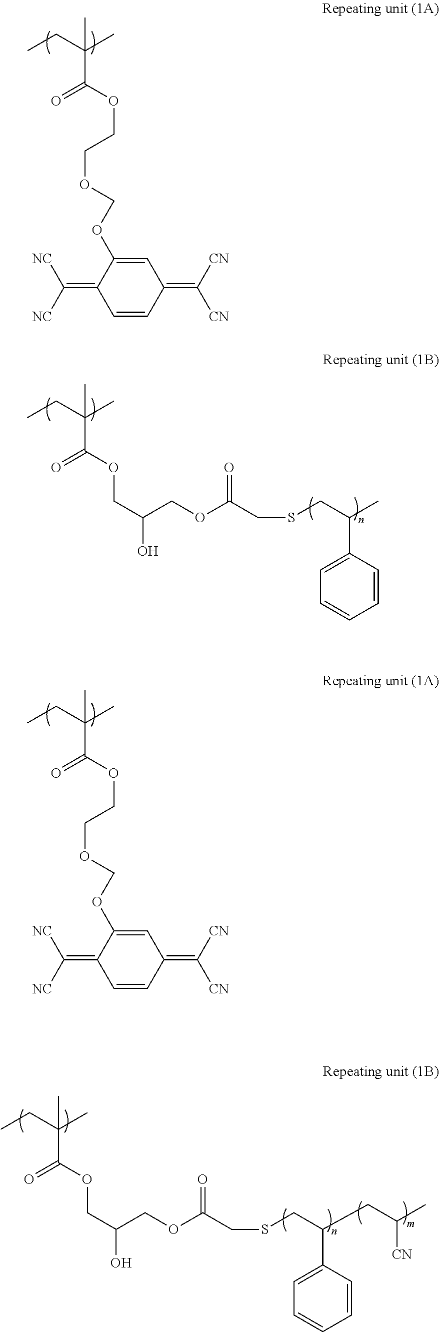

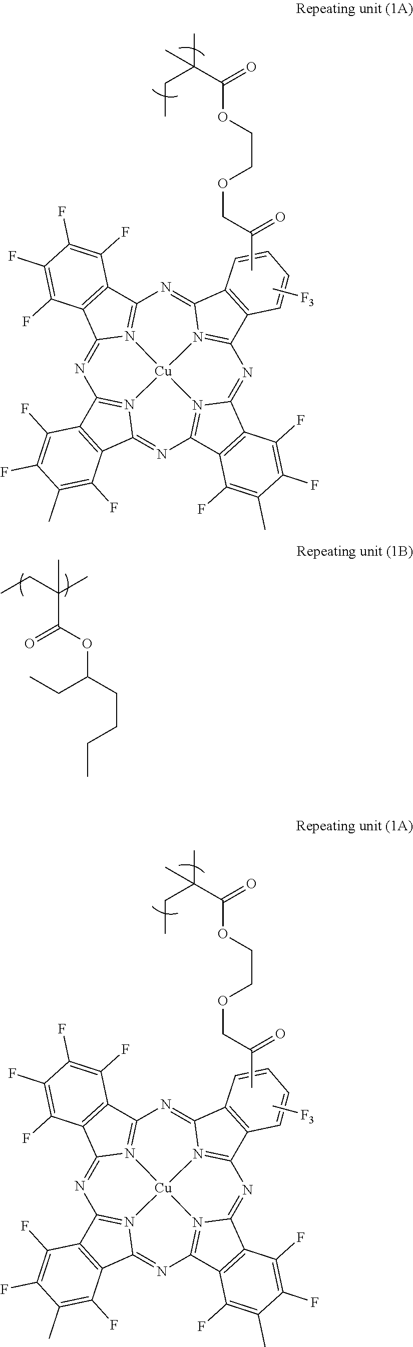

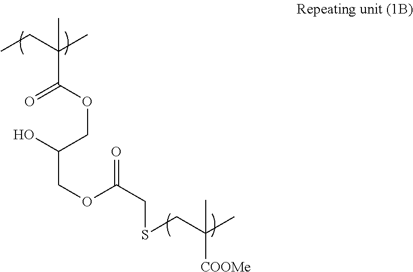

The dispersing agent of the invention may include a repeating unit other than the repeating units (1A) and (1B), and the repeating unit is preferably a copolymer consisting of the repeating units (1A) and (1B).

A copolymer including the repeating units (1A) and (1B) may be any one of a graft copolymer, a block copolymer, a random copolymer and an alternate copolymer. A graft copolymer is preferred since it is easy to uniformly dispose the steric repulsive group at a high density on the surface of a dispersion and to synthesize the graft copolymer. The above-described copolymer can be synthesized using a method in which a monomer and a macromonomer are copolymerized together, thereby obtaining a graft copolymer, a method in which a monomer and a monomer having a polymerization initiation site are copolymerized together and thus are polymerized from a polymer chain, a method in which a polymer reaction is performed between a polymer having a reactive group and another polymer, thereby synthesizing a graft copolymer, or the like. Among these, from the viewpoint of the introduction ratio of a graft chain and the easy control of the graft chain length and the like, the method in which a monomer and a macromonomer are copolymerized together, thereby obtaining a graft copolymer is preferred.

The graft copolymer preferably has a main chain formed by the copolymerization of the repeating unit (1A) and the repeating unit (1B) and has the steric repulsive group in the repeating unit (1B) as a side chain. In this case, the repeating unit (1B) site in the copolymer is preferably formed of a macromonomer. That is, the graft copolymer is preferably synthesized by copolymerizing a macromonomer capable of forming the repeating unit (1B) and a monomer capable of forming the repeating unit (1A).

Regarding the mole-based compositional ratio between the repeating units (1A) and (1B) in the copolymer including the repeating units (1A) and (1B), the repeating unit (1A): the repeating unit (1B) is preferably 20 to 90:80 to 10 and more preferably 40 to 80:60 to 20.

In addition, the weight-average molecular weight of the copolymer is preferably 1,000 to 800,000 and more preferably 10,000 to 300,000. Meanwhile, the weight-average molecular weight can be measured using gel permeation chromatography (GPC). For example, it is possible to calculate the weight-average molecular weight in terms of polystyrene using a high-speed GPC apparatus (for example, HLC-8220GPC (manufactured by Tosoh Corporation)) after dissolving a polymer compound in tetrahydrofuran (THF).

The percentage content of the dispersing agent in the thermoelectric conversion material is preferably 5 parts by mass to 100 parts by mass and more preferably 10 parts by mass to 80 parts by mass, relative to 100 parts by mass of the carbon nanotube, from the viewpoint of the thermoelectric conversion performance.

In the thermoelectric conversion material of the invention, the dispersing agent may be used singly, or two or more kinds thereof may be used in combination.

[(c) Dispersion Medium]

The thermoelectric conversion material of the invention preferably contains a dispersion medium.

The dispersion medium may be any dispersion medium capable of dispersing the carbon nanotube, and water, an organic solvent, and a solvent mixture thereof can be used.

The dispersion medium is preferably an organic solvent, and aliphatic halogen-based solvents such as an alcohol and chloroform, aprotic polar solvents such as N,N-dimethylformamide (DMF), N-methylpyrrolidone (NMP), and dimethyl sulfoxide (DMSO), aromatic solvents such as chlorobenzene, dichlorobenzene, benzene, toluene, xylene, mesitylene, tetralin, tetramethyl benzene, and pyridine, ketone-based solvents such as cyclohexanone, acetone, and methyl ethyl ketone, ether-based solvents such as diethyl ether, tetrahydrofuran (THF), t-butyl methyl ether, dimethoxyethane, and diglyme, and the like are preferred, and aliphatic halogen-based solvents such as chloroform, aprotic polar solvents such as DMF and NMP, aromatic solvents such as dichlorobenzene, xylene, tetralin, and tetramethyl benzene, ether-based solvents such as THF, and the like are more preferred.

In the thermoelectric conversion material of the invention, the dispersion medium can be used singly, or two or more kinds of dispersion media can be used in combination.

In addition, the dispersion medium is preferably degassed in advance. The dissolved oxygen level in the dispersion medium is preferably set to 10 ppm or less. Examples of a degassing method include a method in which ultrasonic waves are radiated at a reduced pressure and a method in which an inert gas such as argon is bubbled.

Furthermore, the dispersion medium is preferably dehydrated in advance. The amount of moisture in the dispersion medium is preferably set to 1,000 ppm or less and more preferably set to 100 ppm or less. As a method for dehydrating the dispersion medium, it is possible to use a well-known method such as the use of a molecular sieve or distillation.

The amount of the dispersion medium in the thermoelectric conversion material is preferably 25% by mass to 99.99% by mass, more preferably 30% by mass to 99.95% by mass, and still more preferably 30% by mass to 99.9% by mass, relative to the total amount of the thermoelectric conversion material.

[Other Components]

The thermoelectric conversion material of the invention may contain other components in addition to the carbon nanotube, the dispersing agent, and the dispersion medium.

Examples of other components include polymer compounds other than the dispersing agent (hereinafter, other polymer compounds), an oxidation inhibitor, a light-fast stabilizer, a heat-resistant stabilizer, and a plasticizer.

Examples of the other polymer compounds include conjugated polymers and non-conjugated polymers.

Examples of the oxidation inhibitor include IRGANOX 1010 (trade name, manufactured by Ciba-Geigy Japan Limited), SUMILIZER GA-80 (trade name, manufactured by Sumitomo Chemical Co., Ltd.), SUMILIZER GS (trade name, manufactured by Sumitomo Chemical Co., Ltd.), and SUMILIZER GM (trade name, manufactured by Sumitomo Chemical Co., Ltd.).

Examples of the light-fast stabilizer include TINUVIN 234 (trade name, manufactured by BASF), CHIMASSORB 81 (trade name, manufactured by BASF), and CYASORB UV-3853 (trade name, manufactured by Sun Chemical Company LTD.).

Examples of the heat-resistant stabilizer include IRGANOX 1726 (trade name, manufactured by BASF). Examples of the plasticizer include ADEKACIZER RS (trade name, manufactured by Adeka Corp.).

The percentage content of the other components is preferably 5% by mass or less and more preferably 0% by mass to 2% by mass, relative to the total solid content of the thermoelectric conversion material.

[Preparation of Thermoelectric Conversion Material]

The thermoelectric conversion material of the invention can be prepared by mixing the respective components described above. Preferably, the thermoelectric conversion material is prepared by mixing the carbon nanotube, the dispersing agent, and the other components as desired into the dispersion medium, and dispersing the carbon nanotube.

There are no particular limitations on the method for preparing the thermoelectric conversion material, and the method can be carried out at a normal temperature and a normal pressure using a conventional mixing apparatus or the like. For example, the thermoelectric conversion material may be produced by stirring, shaking or kneading various components in a solvent, and thereby dissolving or dispersing the components. In order to promote dissolution or dispersion, an ultrasonication treatment may be carried out.

Furthermore, the dispersibility of the carbon nanotube can be increased by heating the solvent to a temperature that is higher than or equal to room temperature and lower than or equal to the boiling point in the dispersing step, by extending the dispersion time, or by increasing the application intensity of stirring, percolation, kneading, ultrasonication or the like.

[Thermoelectric Conversion Element]

A thermoelectric conversion element of the invention has, on a base material, a first electrode, a thermoelectric conversion layer, and a second electrode, and the thermoelectric conversion layer is formed using the thermoelectric conversion material of the invention.

Since the thermoelectric conversion element functions by maintaining a temperature difference in the thickness direction or the surface direction of the thermoelectric conversion layer, the thermoelectric conversion layer needs to have a certain degree of thickness. Therefore, in case in which the thermoelectric conversion layer is formed using a coating method, the thermoelectric conversion material to be applied needs to have favorable coatability and film-forming properties. The thermoelectric conversion material of the invention has favorable dispersibility of the carbon nanotube and is excellent in terms of coatability or film-forming properties, and is thus suitable for being molded and processed into the thermoelectric conversion layer.

As long as the thermoelectric conversion element of the invention has, on a base material, a first electrode, a thermoelectric conversion layer, and a second electrode, and at least one surface of the thermoelectric conversion layer is disposed so as to be in contact with the first electrode and the second electrode, there are no particular limitations on other constitutions such as the positional relationship between the first electrode, the second electrode, and the thermoelectric conversion layer. For example, the thermoelectric conversion element may have an embodiment in which the thermoelectric conversion layer is sandwiched between the first electrode and the second electrode, that is, an embodiment in which the first electrode, the thermoelectric conversion layer, and the second electrode are provided on the base material in this order. In addition, the thermoelectric conversion element may have an embodiment in which the first electrode and the second electrode are disposed so as to be in contact with one surface of the thermoelectric conversion layer, that is, an embodiment in which the first electrode and the second electrode are formed apart from each other on the same base material and the thermoelectric conversion layer is laminated on both electrodes.

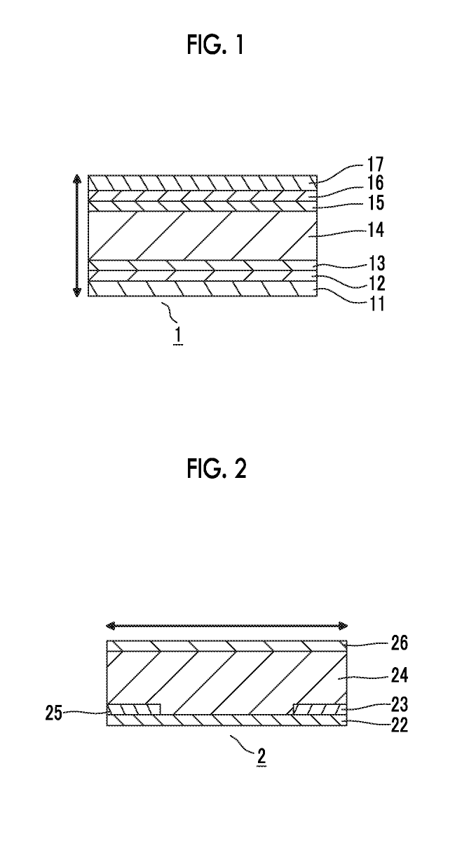

Examples of the structure of the thermoelectric conversion element of the invention include the structures of the element illustrated in FIGS. 1 and 2. In FIGS. 1 and 2, the arrows indicate the directions of temperature differences during the use of the thermoelectric conversion element.

A thermoelectric conversion element 1 illustrated in FIG. 1 comprises a pair of electrodes including a first electrode 13 and a second electrode 15 and a thermoelectric conversion layer 14 formed of the thermoelectric conversion material of the invention between the electrodes 13 and 15 on a first base material 12. A second base material 16 is disposed on the other surface of the second electrode 15, and metal plates 11 and 17 are disposed opposite to each other on the outside of the first base material 12 and the second base material 16.

In a thermoelectric conversion element 2 illustrated in FIG. 2, a first electrode 23 and a second electrode 25 are disposed on a first base material 22, and a thermoelectric conversion layer 24 formed of the thermoelectric conversion material of the invention is provided thereon.

From the viewpoint of protecting the thermoelectric conversion layer, the surface of the thermoelectric conversion layer is preferably covered with the electrode or the base material. For example, as illustrated in FIG. 1, it is preferable that one surface of the thermoelectric conversion layer 14 is covered with the first base material 12 through the first electrode 13 and the other surface is covered with the second base material 16 through the second electrode 15. In this case, the second electrode 15 may be exposed to air as an outermost surface without providing the second base material 16 on the outside of the second electrode 15. In addition, as illustrated in FIG. 2, it is preferable that one surface of the thermoelectric conversion layer 24 is covered with the first electrode 23, the second electrode 25, and the first base material 22 and the other surface is also covered with a second base material 26.

In addition, on the surface (a surface that is pressure-bonded to the thermoelectric conversion layer) of a base material that is used for the thermoelectric conversion element, the electrodes are preferably formed in advance. It is preferable that the base material or the electrodes and the thermoelectric conversion layer are pressure-bonded to each other by heating the members to approximately 100° C. to 200° C. from the viewpoint of improving the adhesiveness.

As the base material (the first base material 12 and the second base material 16 in the thermoelectric conversion element 1) in the thermoelectric conversion element of the invention, it is possible to use a base material such as glass, transparent ceramic, metal, or a plastic film. In the thermoelectric conversion element of the invention, the base material preferably has flexibility and, specifically, preferably has a flexibility at which the endurance number of cycles in a bend test (MIT) by the measurement method regulated by ASTM D2176 is 10,000 cycles or more. The base material having the above-described flexibility is preferably a plastic film, and specific examples thereof include polyester films such as films of polyethylene terephthalate, polyethylene isophthalate, polyethylene naphthalate, polybutylene terephthalate, poly(1,4-cyclohexylene dimethylene terephthalate), polyethylene-2,6-phthalene dicarboxylate, and a polyester film of bisphenol A with iso- and terephthalic acid; polycycloolefine films such as a ZEONOR film (trade name, manufactured by Zeon Corp.), an ARTON film (trade name, manufactured by JSR Corp.), and SUMILITE FS1700 (trade name, manufactured by Sumitomo Bakelite Co., Ltd.); polyimide films such as KAPTON (trade name, manufactured by Du Pont-Toray Co., Ltd.), APICAL (trade name, manufactured by Kaneka Corp.), UPILEX (trade name, manufactured by Ube Industries, Ltd.), and POMIRAN (trade name, manufactured by Arakawa Chemical Industries, Ltd.); polycarbonate films such as PURE-ACE (trade name, manufactured by TEIJIN LIMITED.) and ELMECH (trade name, manufactured by Kaneka Corp.); polyether ether ketone films such as SUMILITE FS1100 (trade name, manufactured by Sumitomo Bakelite Co., Ltd.); and polyphenyl sulfide films such as TORELINA (trade name, manufactured by Toray Industries, Inc.). From the viewpoints of easy availability, heat resistance (preferably at 100° C. or higher), economic efficiency, and effectiveness, commercially available polyethylene terephthalate, polyethylene naphthalate, a variety of polyimides or polycarbonate films, and the like are preferred.

The base material is preferably used after being provided with the electrode on the surface that is pressure-bonded to the thermoelectric conversion layer. As an electrode material forming the first electrode and the second electrode that are provided on the base material, it is possible to use a transparent electrode of ITO, ZnO, or the like; a metal electrode of silver, copper, gold, aluminum, or the like; a carbon material such as CNT or graphene: an organic material such as PEDOT/PSS; an electroconductive paste obtained by dispersing electroconductive fine particles of silver, carbon, or the like; and an electroconductive paste containing a metal nanowire of silver, copper, aluminum, or the like. Among these, a metal electrode of silver, copper, gold, aluminum, or the like or an electroconductive paste containing the above-described metal is preferred.

From the viewpoint of handling properties, durability, and the like, the thickness of the base material is preferably 30 μm to 3,000 μm, more preferably 50 μm to 1,000 μm, still more preferably 100 μm to 1,000 μm, and particularly preferably 200 μm to 800 μm. When the thickness of the base material is set in this range, the thermal conductivity does not decrease, and the thermoelectric conversion layer is not easily damaged due to an external impact.

The layer thickness of the thermoelectric conversion layer is preferably 0.1 μm to 1,000 μm and more preferably 0.5 μm to 100 μm. When the film thickness is set in this range, it is easy to apply a temperature difference, and an increase in the resistance in the film can be prevented.

Generally, the thermoelectric conversion element can be simply manufactured compared with a photoelectric conversion element such as an organic thin film solar cell element. Particularly, when the thermoelectric conversion material of the invention is used, compared with an organic thin film solar cell element, it is not necessary to consider the light absorption efficiency, and thus it is possible to increase the thickness by approximately 100 times to 1,000 times, and the chemical stability with respect to oxygen or moisture in the air improves.

A method for forming the thermoelectric conversion layer is not particularly limited, and, for example, a known coating method such as spin coating, extrusion die coating, blade coating, bar coating, screen printing, stencil printing, roll coating, curtain coating, spray coating, or dip coating can be used. Among these, screen printing is particularly preferred since the adhesiveness of the thermoelectric conversion layer to the electrode is excellent.

After the formation of the film, it is preferable to carry out a drying step as necessary, thereby removing the solvent. For example, the solvent can be volatilized and dried by heating and drying the thermoelectric conversion material or blowing hot air.

The thermoelectric conversion element of the invention exhibits excellent thermoelectric conversion performance and can be preferably used as a power generating element for a thermoelectric power generating component. Specific examples of the power generating element include electric power generators such as a hot spring electrical heat generator, a solar heat power generator, and a waste heat power generator, a power supply for a wrist watch, a semiconductor-driven power supply, and a power supply for a (small-sized) sensor.

### EXAMPLES

Hereinafter, the present invention will be explained in more detail by way of Examples, but the invention is not intended to be limited to these.

Dispersing agents used in the examples will be described below. In the following chemical formulae, the numbers of individual repeating units represent mole %. The molecular weights of these dispersing agents are as described below. The weight-average molecular weight was measured using gel permeation chromatography (GPC).

Dispersing agent 1: Weight-average molecular weight=21,000

Dispersing agent 2: Weight-average molecular weight=21,000

Dispersing agent 3: Weight-average molecular weight=25,000

Dispersing agent c1: Weight-average molecular weight=32,000

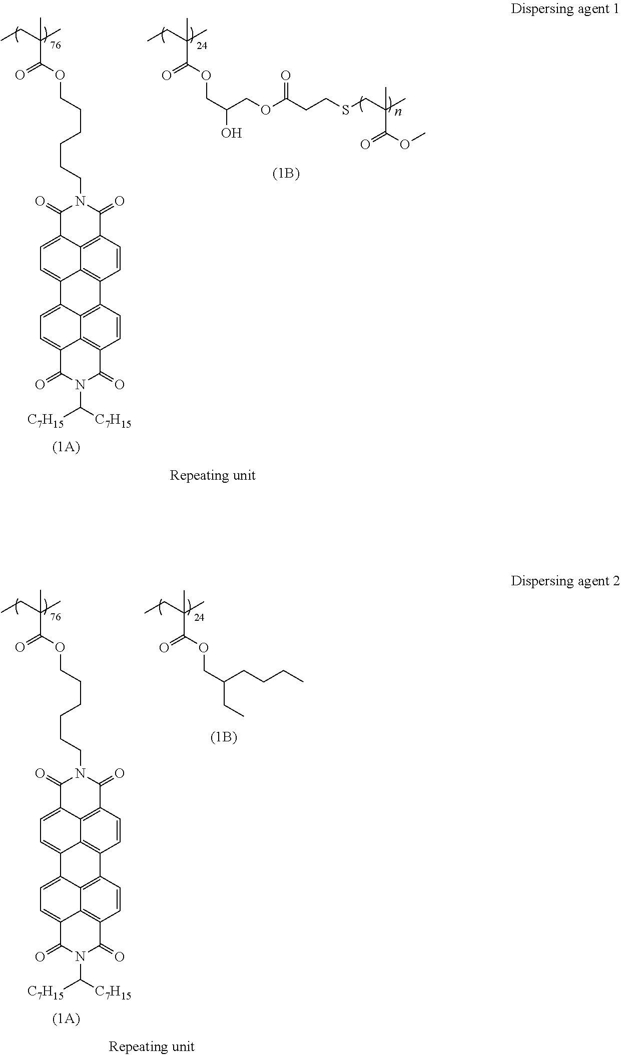

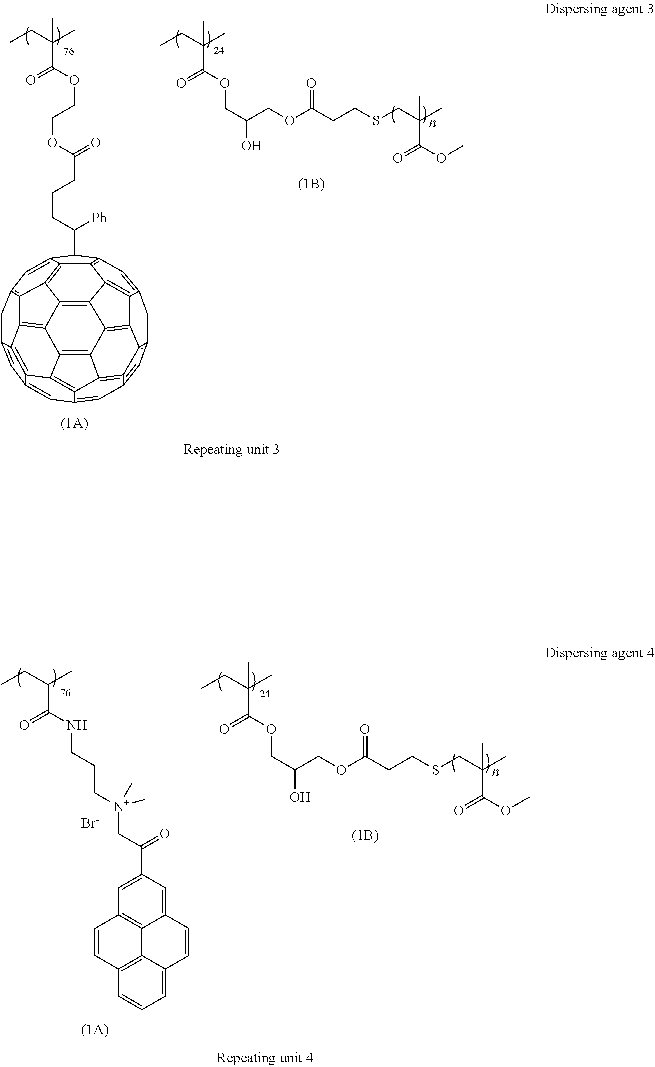

Synthesis of Macromonomer of Polymethyl Methacrylate (PMMA)

100 g of methyl methacrylate and 0.35 g of thiopropionic acid were injected into a 250 mL three-neck flask and were heated to 80° C. After the heating, 17 mg of azobisisobutyronitrile (AIBN, manufactured by Wako Pure Chemical Industries, Ltd.) was injected thereinto and was reacted for 40 minutes, and then, repeatedly, 17 mg of AIBN (manufactured by Wako Pure Chemical Industries, Ltd.) was injected thereinto and was reacted for 40 minutes twice. After that, 10 g of tetrahydrofuran was injected thereinto, thereby ending the reaction. The reaction liquid was precipitated again, thereby obtaining 60 g of an intermediate body A.

15 g of the obtained intermediate body A, 30 g of xylene, 0.28 g of glycidyl methacrylate, 0.01 g of hydroquinone, and 0.01 g of dimethyl laurylamine were injected into a 250 mL three-neck flask and were reacted for five hours under reflux conditions. After that, the reaction liquid was precipitated again, thereby obtaining 10 g of a macromonomer of polymethyl methacrylate (PMMA).

### Synthesis Example 1

### Synthesis of Dispersing Agent 1

4 g of perylene-3,4,9,10-tetracarboxylic dianhydride, 4.5 g of 1-hetpyloctylamine, and 20 g of imidazole were injected into a 500 mL three-neck flask and were reacted at 180° C. for five hours. After the reaction liquid was treated with ethanol and a 2N hydrochloric acid, an organic layer was taken out and was washed with water, and the solvent was removed. The obtained reaction product was column-purified, thereby obtaining 5 g of N,N′-bis(1-heptyloctyl)perylene-3,4,9,10-tetracarboxyl bisimide (compound 1A).

4 g of the compound 1A obtained above, 85 mL of tertiary butanol, and 0.5 g of KOH were injected into a 250 mL three-neck flask, were heated and refluxed, and then were stirred for 30 minutes. The reaction liquid was cooled and then was treated with acetic acid and a 2N hydrochloric acid. After the treatment, the reaction liquid was washed with water, and the solvent was removed, thereby obtaining a solid. The obtained solid was refluxed and heated in 150 mL of an aqueous solution of 10% potassium carbonate for 30 minutes. After the reaction liquid was washed with an aqueous solution of 10% potassium carbonate, a 2N hydrochloric acid, and water, the solvent was removed, thereby obtaining a solid. The obtained solid was refluxed and heated in an aqueous solution of trimethylamine for 30 minutes. The reaction liquid was filtered and then was treated in a 2N hydrochloric acid for 24 hours. The obtained reaction liquid was filtered, then, washed with water, dried, and column-purified, thereby obtaining 1 g of N-(1-heptyloctyl)perylene-3,4,9,10-tetracarboxyl-3,4,-anhydride-9,10-imide (compound 1B).

1 g of the compound 1B obtained above, 0.5 g of 6-aminohexyl alcohol, and 6 g of imidazole were injected into a 250 mL three-neck flask and were reacted at 160° C. for four hours. After the reaction, the reaction liquid was diluted with ethanol and was stirred in a 2N hydrochloric acid for 24 hours. The reaction liquid was filtered and dried, thereby obtaining 1 g of N-(1-heptyloctyl)-N′-(6-aminohexyl)perylene-3,4,9,10-tetracarboxyl bisimide (compound 1C).

1 g of the compound 1C obtained above, 0.3 g of methacrylic acid chloride, 0.3 g of triethylamine, and 3 g of dimethyl acetamide were injected into a 250 mL three-neck flask and were reacted at 5° C. for 12 hours. Ethyl acetate was added to the obtained reaction liquid, the reaction liquid was washed with sodium bicarbonate water and water, and then the solvent was removed, thereby obtaining 0.8 g of a target monomer 1 having a perylene bisimide structure and a methacrylate structure.

0.8 g of the monomer obtained above, 2 g of a macromonomer of PMMA synthesized above, and 4 g of dimethyl acetamide were injected into a 250 mL three-neck flask and were heated at 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries, Ltd.) and reacting V-601 for two hours was repeated twice. The obtained reaction liquid was precipitated again, thereby obtaining 2 g of a target polymer 1 (dispersing agent 1).

### Synthesis Example 2

### Synthesis of Dispersing Agent 2

4 g of dimethyl acetamide was injected into a 250 mL three-neck flask and were heated at 80° C. After 0.8 g of the monomer 1 obtained in the synthesis process of the dispersing agent 1, 2 g of 2-ethylhexyl methacrylate, and 4 g of dimethyl acetamide were added to the solution, a solution obtained by dissolving 0.05 g of a polymerization initiator V-601 (manufactured by Wako Pure Chemical Industries, Ltd.) was added dropwise thereto over two hours. After the dropwise addition, the components were further reacted together for three hours, the obtained reaction liquid was precipitated again, thereby obtaining 2 g of a target polymer 2 (dispersing agent 2).

### Synthesis Example 3

### Synthesis of Dispersing Agent 3

10 g of [60] PCBN (manufactured by Sigma-Aldrich Co. LCC.) and 50 g of ethylene glycol were injected into a 250 mL three-neck flask and were reacted at 80° C. for eight hours. After that, dichloromethane was injected thereinto, the components were washed with water, the solvent was distilled away, and furthermore, the components were column-purified, thereby obtaining 2 g of an intermediate body 3A.

1 g of the intermediate body 3A obtained above, 0.3 g of methacrylic acid chloride, 0.3 g of trimethylamine, and 3 g of dichloromethane were injected into a 250 mL three-neck flask and were reacted at 5° C. for 12 hours. Dichloromethane was added to the obtained reaction liquid, the reaction liquid was washed with sodium bicarbonate water and water, and the solvent was removed, thereby obtaining 0.6 g of a target monomer 3 having a C60 structure and a methacrylate structure.

0.6 g of the monomer 3 obtained above, 2 g of a macromonomer of PMMA synthesized above, and 4 g of dimethyl acetamide were injected into a 250 mL three-neck flask and were heated at 80° C. After that, 0.0127 g of a polymerization initiator V-601 (manufactured by Wako Pure Chemical Industries, Ltd.) was injected thereinto and was reacted for two hours. Furthermore, a step of injecting 0.0127 g of V-601 (manufactured by Wako Pure Chemical Industries. Ltd.) and reacting V-601 for two hours was repeated twice. The obtained reaction liquid was precipitated again, thereby obtaining 2 g of a target polymer 3 (dispersing agent 3).

### Synthesis Example 4

### Synthesis of Dispersing Agent c1

5 g of bromoacetyl pylene (manufactured by Sigma-Aldrich Co. LCC.), 2.7 g of dimethyl propyl acrylamide, and 100 mL of tetrahydrofuran were injected into a 250 mL three-neck flask and were reacted at room temperature for three hours. The precipitated solid was filtered, thereby obtaining 6 g of a monomer c1.

2.5 g of the monomer c1 obtained above, 10 g of a macromonomer of PMMA synthesized above, and 20 g of dimethyl acetamide were injected into a 250 mL, three-neck flask and were heated at 80° C. After that, 0.03 g of a polymerization initiator V-601 (manufactured by Wako Pure Chemical Industries, Ltd.) was injected thereinto and was reacted for two hours. Furthermore, a step of injecting 0.03 g of V-601 (manufactured by Wako Pure Chemical Industries, Ltd.) and reacting V-601 for two hours was repeated twice. The obtained reaction liquid was precipitated again, thereby obtaining 10 g of a target dispersing agent c1.

### Example 1

### Thermoelectric Conversion Element 101

5 mg of the dispersing agent 1 and 5 mg of a single-layer CNT (manufactured by KH Chemicals) were added to 10 ml of ortho-dichlorobenzene and were dispersed using an ultrasonic homogenizer for 20 minutes, thereby preparing a dispersion liquid 101.

As a base material, a glass substrate having a thickness of 1.1 mm and a size of 40 mm×50 mm was used. After this base material was ultrasonic-washed in acetone, a UV-ozone treatment was carried out for 10 minutes. After that, gold pieces having a size of 30 mm×5 mm and a thickness of 10 nm were respectively formed on both end part sides of the base material as a first electrode and a second electrode.

A TEFLON (registered trademark) frame was attached onto the base material on which the electrodes were formed, the prepared dispersion liquid 101 was poured into the frame and was dried on a hot plate at 60° C. for one hour, the frame was removed after the drying, and a thermoelectric conversion layer having a thickness of approximately 1.1 μm was formed, thereby producing a thermoelectric conversion element 101 having the constitution illustrated in FIG. 1.

Dispersion liquids 102, 103, and c101 and thermoelectric conversion elements 102, 103, and c101 were produced in the same manner as the dispersion liquid 101 and the thermoelectric conversion element 101, except that the dispersing agents shown in Table 1 were used instead of the dispersing agent 1.

The dispersibility of CNT and the thermoelectromotive force of the thermoelectric conversion element were evaluated using the following methods. In addition, the HOMO and LUMO energy levels of the CNT used and the dispersing agent used were measured using the following methods.

[Dispersibility]

The dispersion liquid was left to stand at room temperature for two days, and the sedimentation property of CNT was evaluated using the following standards.

A: The sedimentation of CNT was visually confirmed.

B: The sedimentation of CNT was not visually confirmed.

[Thermoelectromotive Force S]

The first electrode of each thermoelectric conversion element was disposed on a hot plate maintained at a constant temperature, and a Peltier device for temperature control was disposed on the second electrode.

While the temperature of the hot plate was maintained constant (100° C.), the temperature of the Peltier device was decreased, and thereby a temperature difference (in the range of more than 0 K but no more than 4 K) was applied between the two electrodes.

At this time, the thermoelectromotive force (μV) generated between the two electrodes was divided by the particular temperature difference (K) generated between the two electrodes, and thereby the thermoelectromotive force S per unit temperature difference (μV/K) was calculated.

[Measurement of HOMO and LUMO Energy Levels]

The HOMO energy levels and the LUMO energy levels of each of CNT and the dispersing agent were determined using the following method.

The HOMO energy level was measured by means of photoelectron spectroscopy (manufactured by Riken Keiki Co., Ltd.: AC-2) after a single coated film of each component was produced on a glass substrate. The LUMO energy level was calculated by measuring the band gap using an ultraviolet and visible spectrophotometer (manufactured by Shimadzu Corporation: UV-3600) and then adding the band gap to the previously-measured HOMO energy level.

Next, the difference between the absolute value of the energy level of the HOMO of CNT and the absolute value of the energy level of the LUMO of the dispersing agent |HOMO of CNT|−|LUMO of dispersing agent| was obtained.

TABLE 1

| | | \|HOMO of CNT\|-\|LUMO of | | Thermoelectromotive | |
|---|---|---|---|---|---|
| Thermoelectric | Dispersing | dispersing agent\| | | force S | |
| conversion element | agent | (eV) | Dispersibility | (μV/K) | Note |
| 101 | 1 | 0.3 | A | 50 | Present |
| | | | | | Invention |
| 102 | 2 | 0.3 | A | 45 | Present |
| | | | | | Invention |
| 103 | 3 | 0.7 | A | 45 | Present |
| | | | | | Invention |
| c101 | c1 | 2.0 | A | 30 | Reference |
| | | | | | example |

As is clear from Table 1, in the CNT dispersion liquids 101 to 103 for which the dispersing agents 1 to 3 having the electron-accepting group were used, excellent dispersibility was exhibited. Furthermore, in the thermoelectric conversion elements 101 to 103 for which the above-described dispersing agents were used, compared with the thermoelectric conversion element c101 for which the dispersing agent c1 not having the electron-accepting group was used, a higher thermoelectromotive force were exhibited.

### Example 2

A thermoelectric conversion element 201 was produced in the same manner as the thermoelectric conversion element 101, except that the base material was changed to a polyimide substrate (manufactured by Du Pont-Toray Co., Ltd.: KAPTON) in Example 1.

The thermoelectric conversion element 201 exhibited as high a thermoelectromotive force as that of the thermoelectric conversion element 101, could be bent, and was significantly flexible.

The invention has been explained together with the examples, but the present inventors do not intend to limit the invention in any detailed parts of the explanation unless particularly otherwise described and consider that the invention should be widely interpreted within the spirit and scope of the invention described in the accompanying claims.

### EXPLANATION OF REFERENCES

1, 2: Thermoelectric conversion element
11, 17: Metal plate
12, 22: First base material
13, 23: First electrode
14, 24: Thermoelectric conversion layer
15, 25: Second electrode
16, 26: Second base material

What is claimed is:

1. A thermoelectric conversion material comprising:
(a) a carbon nanotube; and
(b) a dispersing agent including a repeating unit represented by General Formula (1A) below and a repeating unit represented by General Formula (1B) below: 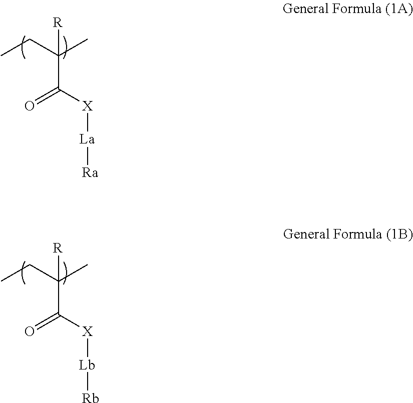
in General Formula (1A), Ra represents an electron-accepting group; La represents a single bond or a divalent linking group; R represents a hydrogen atom or an alkyl group having 1 to 4 carbon atoms; and X represents an oxygen atom or —NH—, and
in General Formula (1B), Rb represents a monovalent group derived from a polyalkylene oxide compound, a poly(meth)acrylate compound, a polysiloxane compound, a polyacrylonitrile compound, or a polystyrene compound, a monovalent group obtained by combining the above-described compounds, or an alkyl group having 5 or more carbon atoms; Lb represents a single bond or a divalent linking group; and R and X are identical to those in General Formula (1A).

2. The thermoelectric conversion material according to claim 1,
wherein (b) the dispersing agent satisfies Expression (I) below:
0.1 eV≦|HOMO of carbon nanotube|−|LUMO of dispersing agent|≦1.9 eV Expression (I)
in Expression (I), |HOMO of carbon nanotube| represents an absolute value of an energy level of a highest occupied molecular orbital (HOMO) of the carbon nanotube, and |LUMO of dispersing agent| represents an absolute value of an energy level of a lowest unoccupied molecular orbital (LUMO) of the dispersing agent, respectively.

3. The thermoelectric conversion material according to claim 1,
wherein, in General Formula (1A), Ra is a monovalent group derived from a perylene bisimide compound, a tetracyanoquinodimethane compound, a phthalocyanine compound, a C60 fullerene compound, or a C70 fullerene compound.

4. The thermoelectric conversion material according to claim 1,
wherein, in General Formula (1B), Rb is a monovalent group derived from a poly(meth)acrylate compound.

5. The thermoelectric conversion material according to claim 1, comprising:
a solvent.

6. A thermoelectric conversion element comprising, on a base material:
a first electrode;
a thermoelectric conversion layer; and
a second electrode,
wherein the thermoelectric conversion layer is formed using the thermoelectric conversion material according to claim 1.
